(19) United States
(12) Patent Application Publication
(10) Pub. No.: US 2026/0040583 A1
(43) Pub. Date: Feb. 5, 2026

(54) LOGIC-UPPERMOST SEMICONDUCTOR DEVICE ASSEMBLIES WITH MULTI-RETICLE DIES AND RETICLE-BRIDGING CONDUCTORS

(71) Applicant: Micron Technology, Inc., Boise, ID (US)

(72) Inventors: Bharat Bhushan, Singapore (SG); Kunal R. Parekh, Boise, ID (US); Akshay N. Singh, Boise, ID (US); Ameen D. Akel, Rancho Cordova, CA (US)

(21) Appl. No.: 19/281,121

(22) Filed: Jul. 25, 2025

Related U.S. Application Data
(60) Provisional application No. 63/677,964, filed on Jul. 31, 2024.

(51) Int. Cl. H01L 23/00; H01L 21/48; H01L 23/48; H01L 23/498; H01L 23/538; H01L 25/065; H10B 80/00

(52) U.S. Cl. CPC H01L 24/08; H01L 23/481; H01L 23/5385; H01L 24/80; H01L 25/0657; H10B 80/00; H01L 21/4853; H01L 23/49816; H01L 2224/08145; H01L 2224/08225; H01L 2224/80895; H01L 2224/80896; H01L 2225/06541; H01L 2225/06565

(57) ABSTRACT

A semiconductor device assembly includes a plurality of stacks of semiconductor devices, each including multiple devices operably coupled by TSVs to external package contacts through an RDL, and a device connection layer formed over the plurality of stacks and including a first plurality of contacts coupled to the TSVs, a second plurality of contacts facing away from the TSVs, a first plurality of conductors operably coupling contacts of the first plurality to corresponding contacts of the second plurality, and a second plurality of conductors operably coupling contacts of the second plurality to other contacts of the second plurality. The assembly further includes a multi-reticle semiconductor device disposed over the device connection layer and including a continuous semiconductor substrate having a plurality of circuit regions separated by a reticle-edge region absent any electrical conductors. The second plurality of conductors in the device connection layer operably interconnect the plurality of circuit regions.

### CROSS-REFERENCE TO RELATED APPLICATION(S)

The present application claims priority to U.S. Provisional Patent Application No. 63/677,964, filed Jul. 31, 2024, the disclosure of which is incorporated herein by reference in its entirety.

### TECHNICAL FIELD

The present disclosure generally relates to semiconductor device assemblies, and more particularly relates to logic-uppermost semiconductor device assemblies with multi-reticle dies and reticle-bridging conductors.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1 through 6 are simplified schematic cross-sectional views of different stages of the manufacturing process of an example semiconductor device assembly in accordance with embodiments of the present technology.

FIG. 7 is a simplified schematic cross-sectional view of a semiconductor device assembly in accordance with embodiments of the present technology.

FIGS. 8 through 13 are simplified schematic cross-sectional views of different stages of the manufacturing process of an example semiconductor device assembly in accordance with embodiments of the present technology.

FIG. 14 is a simplified schematic cross-sectional view of a semiconductor device assembly in accordance with embodiments of the present technology.

FIG. 15 is a simplified schematic partial plan view of a semiconductor device assembly in accordance with embodiments of the present technology.

FIG. 16 is a flow chart illustrating a method of making a semiconductor device assembly in accordance with an embodiment of the present technology.

FIG. 17 is a schematic view showing a system that includes a semiconductor device assembly configured in accordance with an embodiment of the present technology.

### DETAILED DESCRIPTION

The demand for greater performance from semiconductor devices appears to be insatiable. To increase the performance of a device, more features can be included in a device of given size by shrinking the feature dimensions through lithography improvements. As feature shrink nears theoretical limits, however, adding more features has driven an increase in the size (i.e., footprint) of semiconductor devices. With the footprint of semiconductor devices increasing up to the limit of lithographic reticle size (a limit which would require dramatic re-tooling of an entire industry to overcome), increasing the capability of semiconductor devices may be accomplished by integrating multiple reticle-limited semiconductor devices into a single assembly.

Reticle-limited semiconductor devices have a footprint greater than the size of a single reticle field (e.g., current EUV reticle sizes are limited to about 858 mm²) and include multiple reticle-sized circuit areas that, due to the limitations of accurately aligning two different reticle fields, may be spaced apart from one another by a region of un-patterned silicon substrate with no conductors or other circuit features therein (e.g., resembling two discrete dies in an un-singulated portion of a semiconductor wafer). Unlike two discrete dies in an un-singulated portion of semiconductor substrate, however, in a reticle-limited semiconductor device the multiple reticle-limited circuit areas may not be designed identically, however, and may include features intended to connected to each other across the un-patterned region of the substrate (e.g., by subsequent BEOL metallization or by connected to an interposer).

A challenge with these approaches to coupling the discrete circuit regions of a multi-reticle semiconductor device is the additional manufacturing cost, package size (e.g., from a dedicated interposer with solder bond line) and increased circuit path length (e.g. interposed between the multi-reticle semiconductor device and its host and/or between the multi-reticle semiconductor device and auxiliary devices integrated with it, such as memory). To solve these drawbacks and others, embodiments of the present disclosure provide semiconductor device assemblies with a prefabricated device connection layer that can be directly bonded, in a wafer-level operation, to a multi-reticle semiconductor device. The device connection layer can couple not only the discrete circuit regions of the multi-reticle semiconductor device to each other, but also the multi-reticle semiconductor device to other semiconductor devices in a heterogenous device assembly, such as memory, as well as to external package contacts (e.g., by conductive paths extending through the other semiconductor devices in the assembly).

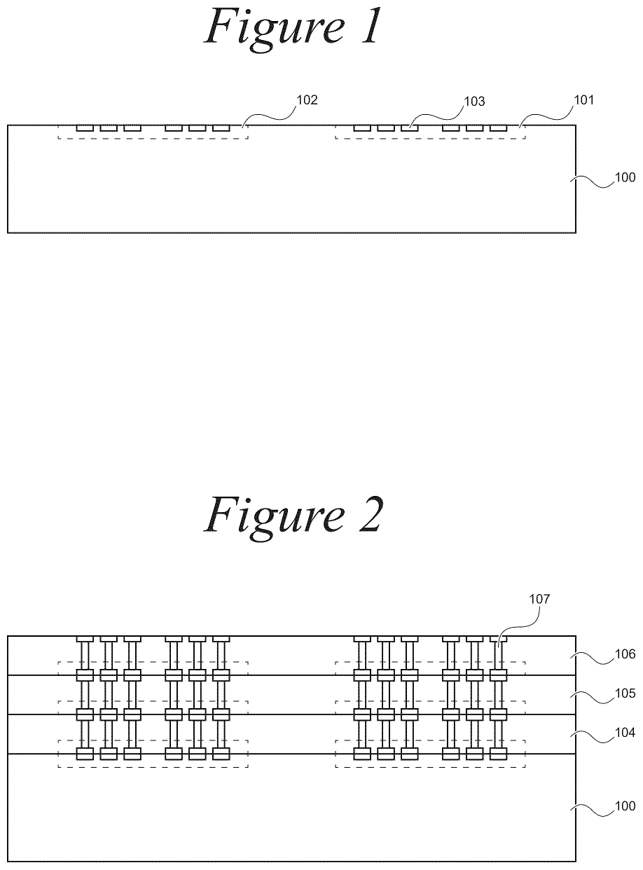

FIGS. 1 through 6 are simplified schematic cross-sectional views of different stages of the manufacturing process of an example semiconductor device assembly in accordance with embodiments of the present technology. Turning to FIG. 1, multiple semiconductor memory devices 101 & 102 are shown still in wafer format, disposed in an active region of wafer 100. Wafer 100 may also be referred to as top memory device wafer. Each memory device 101 or 102 is formed using a separate reticle shot. In one aspect, there are multiple memory devices within each representative memory device 101 and 102. For example, each memory device 101 or 102 may include at least 4, 6, 8, 10, or more unsingulated memory devices. In one aspect, the semiconductor memory devices 101 & 102 include a semiconductor substrate (e.g., silicon substrate) and multiple dielectric and metal layers that are part of the backend of the line layer (BEOL). The memory devices 101 & 102 include contact structures 103 for forming interconnects with additional devices by a wafer-level hybrid bonding process. In one aspect, the contact structures 103 are formed on the frontside of the memory devices 101 &102. These contact structures 103 may be formed using a damascene process. The contact structures 103 are connected to BEOL through via (e.g., tungsten or copper via) and probe pads (e.g., aluminum pads). As shown in FIG. 2, additional wafers 104-106 with additional semiconductor devices (outlined in dashed lines) can be hybrid-bonded to form stacks of devices coupled by the contact structures 103 and TSVs 107 vertically aligned therewith. The TSVs 107 may include either tungsten or copper material as conductive core. Furthermore, the TSVs 107 may be using a via last process or a via middle process. In one aspect, the additional wafers 104-106 are coupled to the wafer 100 by wafer-to-wafer (W2 W) bonding. Also, in one aspect, wafer 100 is bonded to wafer 104 through front-to-back (F2B) configuration, similar to wafer 104 bonding with wafer 105 and wafer 105 bonding with wafer 106. In one aspect, there may be 8 wafers bonded together. In another aspect, there may be more than 8 wafer bonded together such as at least be 12 wafers, 16 wafers, or 24 wafers. The hybrid bonding occurs between the contact structures 103 on the frontside of each wafer 100, 104-106 with backside corresponding contacts of the wafer it is being bonded. The backside contacts are formed using a damascene process after a TSV reveal process.

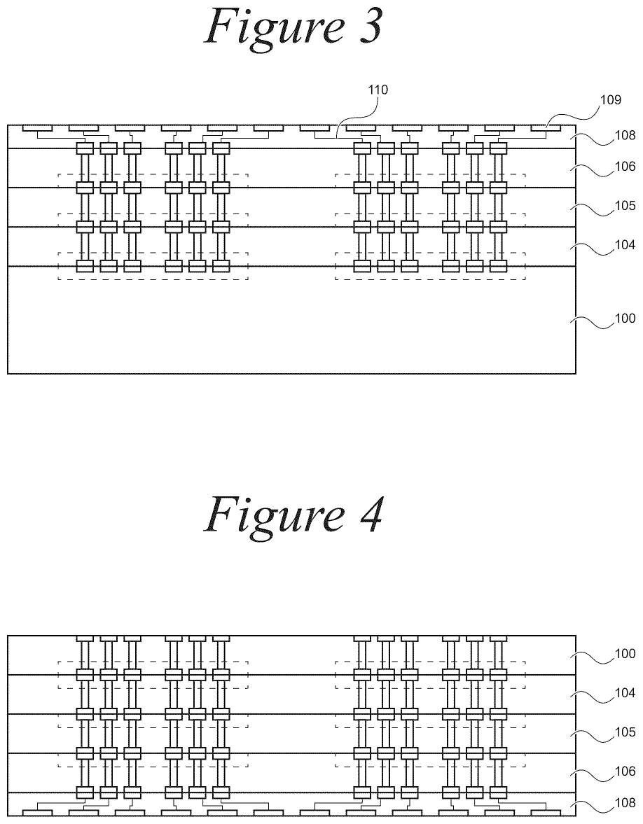

As is illustrated in FIG. 3, a redistribution layer (RDL) 108 can be formed over the stack of wafers 100 and 104-106 from FIG. 2. In one aspect, the device connection layer 108 may be a data proximity layer, which includes substrate, dielectric, and metallization layers. The device connection layer 108 may be connected to wafer 106 through wafer-to-wafer bonding and in the face-to-face (F2F) configuration. In one aspect, the device connection layer 108 may be used for connecting with memory devices 101 and 102 of respective wafers 100, 104, and 106. The device connection layer may also be used to manage the column of memory devices 101 and 102 and any repairs associated with TSVs. In one aspect, the via through the device connection layer 108 can have a different pitch than the via through the stacks of wafers 100, 104-106. The via going through device connection layer 108 may also have a different conductive composition compared to the via through the stacks of wafers 100, 104-106. The RDL can be formed with back end of line (BEOL) metallization processes well known to those of skill in the art. For example, iteratively depositing and patterning dielectric material, and plating metal such as copper into the patterned openings in the dielectric material, permits the construction of external contacts 109 and internal contacts (not labeled), as well as the conductive metal structures 110 that couple the internal contacts and external contacts 110 to each other.

In the present example embodiment, wafer 100 has been illustrated as a “thick” wafer that has not been thinned, and which does not yet include TSVs, as a full-thickness wafer provides robust mechanical support for a stacking operation, as will be readily understood by one of skill in the art. Following the formation of RDL on the wafer stack, the thick wafer 100 can be thinned to reduce the overall height of the eventual assembly, and have TSVs formed therein, as illustrated in FIG. 4. In other embodiments, however, rather than using a thick wafer to support the bonding operations illustrated in FIGS. 2 and 4, wafer 100 could be replaced with a thinned wafer like the other wafers 104-106 that is temporarily bonded to a carrier wafer that provides the desired mechanical support, such that all the wafers 100 and 104-106 would be bonded front-to-back (rather than with a front-to-front bond between wafer 100 and 104, as illustrated).

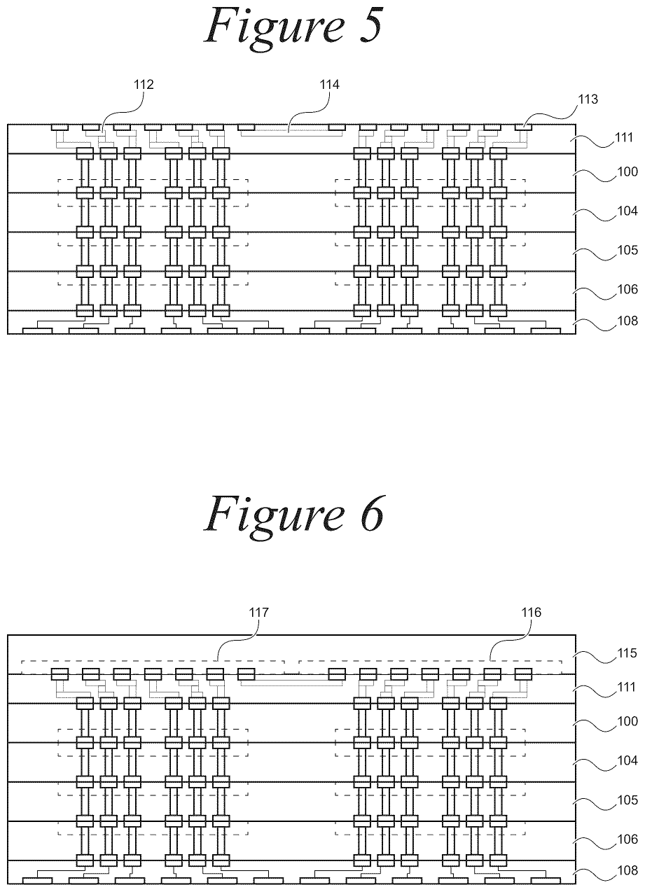

As is illustrated in FIG. 5, a device connection layer 111 can be formed over the stack of wafers 100 and 104-106 from FIG. 4. The device connection layer can be formed like a redistribution layer, with back end of line (BEOL) metallization processes well known to those of skill in the art. For example, iteratively depositing and patterning dielectric material, and plating metal such as copper into the patterned openings in the dielectric material, permits the construction of metal contacts 113 both facing the exposed contacts 103 of wafer 100 and outwardly from the stack, as well as the conductive metal structures 112 that couple the contacts 113 on the wafer-facing (i.e., lower in the orientation of FIG. 5) side of the device connection layer 111 to contacts 113 on the outwardly-facing (i.e., upper in the orientation of FIG. 5) side of the device connection layer 111. The contacts 113 on the outwardly facing side of the device connection layer 111 include a subset that are not coupled to wafer-facing contacts 113 but are rather coupled by reticle-bridging conductors 114 (one pair is shown in the cross-sectional view of FIG. 5, additional pairs of the subset are illustrated in FIG. 15, below). The reticle-bridging conductors 114 can provide inter-region connectivity to a multi-reticle semiconductor device with multiple discrete circuit regions, as shown and described in greater detail below.

Turning to FIG. 6, a wafer 115 including a multi-reticle semiconductor device with two discrete reticle-limited circuit regions 116 and 117 has been hybrid-bonded (i.e., with a dielectric-dielectric bond in regions without conductive contacts, and with a solder-free direct metal-metal bond in regions where contacts of wafer 115 align with the contacts 113 of the device connection layer 111) to the device connection layer 111. Because of the reticle-limited size of the circuit regions 116 and 117, there are no conductors disposed within the region separating them, and prior to bonding the wafer 115 to the device connection layer 111, the circuit regions 116 and 117 are electrically isolated from one another. After the bonding operation however, reticle-bridging conductors 114 operably couple contacts from one circuit area 116 to the other 117, providing inter-region connectivity and permitting the multi-reticle semiconductor device to function as a single integrated device.

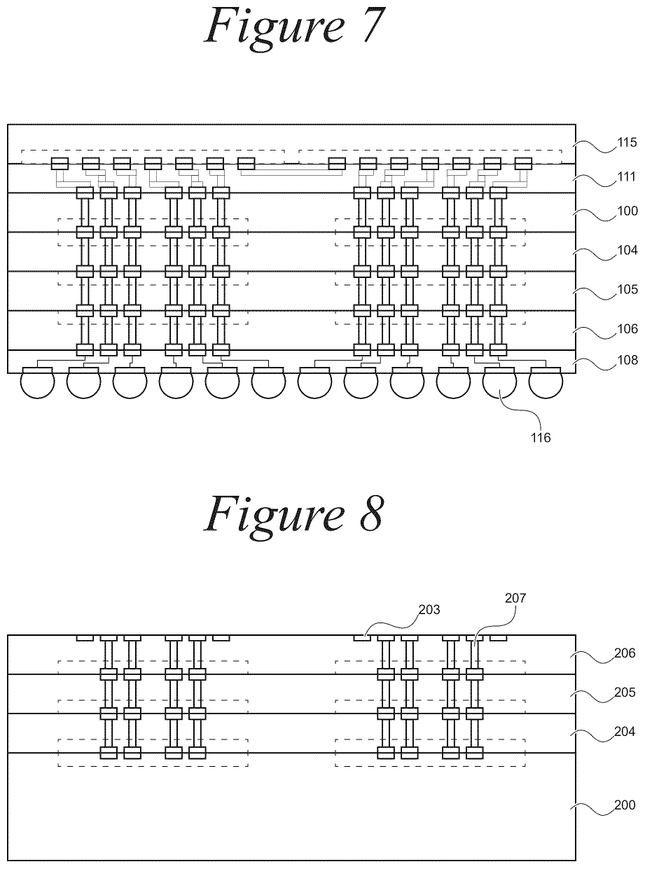

Turning to FIG. 7, a simplified schematic cross-sectional view of a semiconductor device assembly is illustrated after fabrication is complete in accordance with one embodiment of the present technology. Solder balls 116 can be formed on RDL 108 for connection to higher-level devices, and the wafer stack can also be singulated at this point, such that the sidewalls illustrated in the Figure correspond to exterior surfaces of the singulated device.

In accordance with another aspect of the present disclosure, the sub-assembly illustrated in FIG. 5 can be modified to include through-stack vias for connecting the RDL 108 directly to the device connection layer 111, so that signals (e.g., i/o, ground, power, etc.) can be directly provided to the multi-reticle semiconductor device from an external package contact without connecting to circuit elements of the semiconductor devices (e.g., memory devices) between the RDL 108 and the device connection layer 111. For example, FIGS. 8 through 13 are simplified schematic cross-sectional views of different stages of the manufacturing process of an example semiconductor device assembly in accordance with embodiments of the present technology.

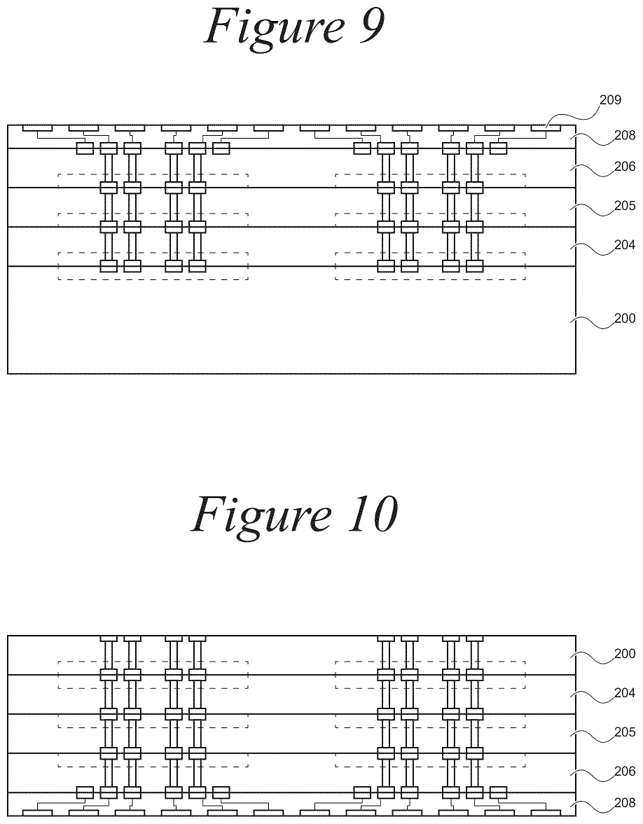

As shown in FIG. 8, in a step analogous to that illustrated in FIG. 2, above, additional wafers 204-206 with additional semiconductor devices (outlined in dashed lines) can be hybrid-bonded to a thick device wafer 200 to form stacks of devices coupled by the contact structures 203 and TSVs 207 vertically aligned therewith. The uppermost wafer 206 include contact structures 203 not aligned with any TSV, for connection to a through-stack via in a later step. Turning to FIG. 9, an RDL 208 can be formed over the stack of wafers 200 and 204-206 from FIG. 8. The RDL can be formed with back end of line (BEOL) metallization processes well known to those of skill in the art. For example, iteratively depositing and patterning dielectric material, and plating metal such as copper into the patterned openings in the dielectric material, permits the construction of external contacts 209 and internal contacts (not labeled), as well as the conductive metal structures that couple the internal contacts and external contacts 209 to each other.

In the present example embodiment, wafer 200 has been illustrated as a “thick” wafer that has not been thinned, and which does not yet include TSVs, as a full-thickness wafer provides robust mechanical support for a stacking operation, as will be readily understood by one of skill in the art. Following the formation of RDL on the wafer stack, the thick wafer 200 can be thinned to reduce the overall height of the eventual assembly, and have TSVs formed therein, as illustrated in FIG. 10. In other embodiments, however, rather than using a thick wafer to support the bonding operations illustrated in FIG. 8, wafer 200 could be replaced with a thinned wafer like the other wafers 204-206 that is temporarily bonded to a carrier wafer that provides the desired mechanical support, such that all the wafers 200 and 204-206 would be bonded front-to-back (rather than with a front-to-front bond between wafer 200 and 204, as illustrated).

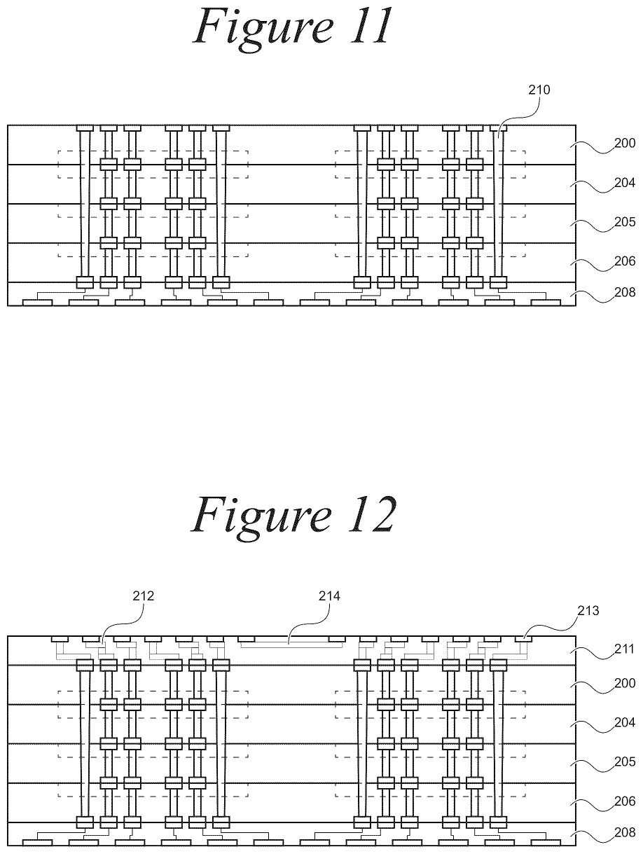

Turning to FIG. 11, though stack vias 210 can be formed through wafers 200 and 204-206 by etching an opening aligned with the contact structures 203 not already connected via TSV and plating a conductive metal (e.g., copper, tungsten, etc.) into the opening. The process may be a dual-damascene process, such as is commonly used to form TSVs with integrated contact pads. Due to the aspect ratio of the etching operation, a continuous taper from one end to the other of the through-stack vias 210 may be observed.

Turning to FIG. 12, a device connection layer 211 can be formed over the stack of wafers 200 and 204-206 from FIG. 11. The device connection layer can be formed like a redistribution layer, with back end of line (BEOL) metallization processes well known to those of skill in the art. For example, iteratively depositing and patterning dielectric material, and plating metal such as copper into the patterned openings in the dielectric material, permits the construction of metal contacts 213 both facing the exposed contacts 203 of wafer 200 and outwardly from the stack, as well as the conductive metal structures 212 that couple the contacts 213 on the wafer-facing (i.e., lower in the orientation of FIG. 12) side of the device connection layer 211 to contacts 213 on the outwardly-facing (i.e., upper in the orientation of FIG. 12) side of the device connection layer 211. The contacts 213 on the outwardly facing side of the device connection layer 211 include a subset that are not coupled to wafer-facing contacts 213 but are rather coupled by reticle-bridging conductors 214 (one pair is shown in the cross-sectional view of FIG. 12, additional pairs of the subset are illustrated in FIG. 15, below). The reticle-bridging conductors 214 can provide inter-region connectivity to a multi-reticle semiconductor device with multiple discrete circuit regions, as shown and described in greater detail below.

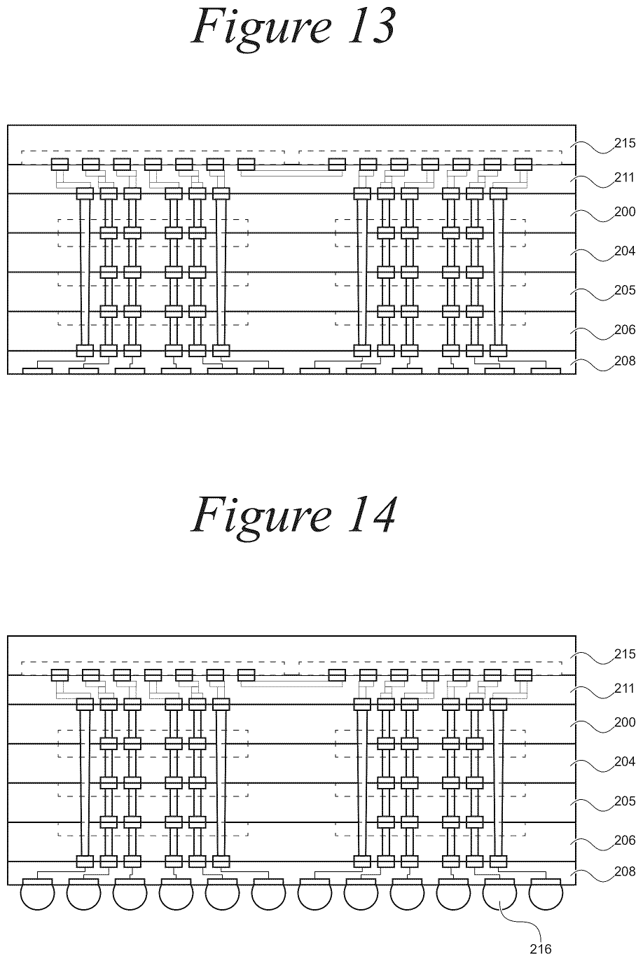

Turning to FIG. 13, a wafer 215 including a multi-reticle semiconductor device with two discrete reticle-limited circuit regions (illustrated in dotted lines) has been hybrid-bonded (i.e., with a dielectric-dielectric bond in regions without conductive contacts, and with a solder-free direct metal-metal bond in regions where contacts of wafer 215 align with the contacts 213 of the device connection layer 211) to the device connection layer 211. Because of the reticle-limited size of the circuit regions, there are no conductors disposed within the region separating them, and prior to bonding the wafer 215 to the device connection layer 211, the circuit regions are electrically isolated from one another. After the bonding operation however, reticle-bridging conductors 214 operably couple contacts from one circuit area to the other, providing inter-region connectivity and permitting the multi-reticle semiconductor device to function as a single integrated device.

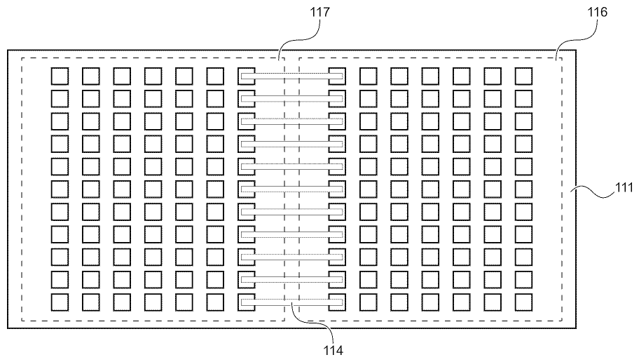

Turning to FIG. 14, a simplified schematic cross-sectional view of a semiconductor device assembly is illustrated after fabrication is complete in accordance with one embodiment of the present technology. Solder balls 216 can be formed on RDL 208 for connection to higher-level devices, and the wafer stack can also be singulated at this point, such that the sidewalls illustrated in the Figure correspond to exterior surfaces of the singulated device.

Turning to FIG. 15, a simplified schematic partial plan view of a semiconductor device assembly in accordance with embodiments of the present technology illustrates additional details of the device connection layer 111. As can be seen with reference to FIG. 15, device connection layer 111 includes multiple reticle-bridging conductors 114 arranged to electrically connect pair of contacts 113 associated with the discrete reticle-limited circuit areas 116 and 117 of the multi-reticle semiconductor device. Although in the present example embodiment, a multi-reticle semiconductor device is illustrated and described as including two discrete circuit areas 116 and 117, in other embodiments a multi-reticle semiconductor device can include more than two circuit areas, and the reticle bridging conductors 114 of the device connection layer 111 may couple contacts 113 to one another in a one-to-one, a one-to-many, and/or a many-to-many topology, as may be desirable for different multi-reticle semiconductor device designs.

Although in the foregoing example embodiments semiconductor device assemblies have been illustrated with two stacks of memory devices on a single multi-reticle semiconductor device, in other embodiments greater or lesser numbers of stacks may be provided over a multi-reticle semiconductor device. Moreover, memory devices so provided may comprise a single type of memory, (e.g., NAND or DRAM or PCM or SRAM or MRAM, etc.) or a mixture of different types of memory (e.g., NAND and/or DRAM and/or PCM and/or SRAM and/or MRAM, etc.). Still further, although stacks have been illustrated with four memory devices vertically aligned, in other embodiments different stack heights may be implemented with fewer (e.g., one, two, or three) or more (e.g., five, six, eight, ten, twelve, etc.) layers of memory devices. In this regard, the wafers 100, 104-106 including memory devices could be reconstituted wafers with known good dies to limit the exponential reduction in yield associated with taller stacks of devices from unsingulated wafers. Similarly, the multi-reticle semiconductor device wafer 112 could be a reconstituted or heterogenous device wafer.

Although in the foregoing example embodiments semiconductor device assemblies have been illustrated with wafers facing the same direction (e.g., with active surfaces bonded to inactive surfaces), in other embodiments a stack of wafers may be bonded with active surfaces facing in different directions (or, mutatis mutandis, all facing the opposite way than illustrated, with back surfaces facing the external package contacts).

Although in the foregoing example embodiments semiconductor device assemblies have been illustrated with wafers bonded exclusively with a hybrid bonding approach, in other embodiments other wafer bonding approaches (e.g., solder interconnects) could be used in the alternative or additionally.

In accordance with one aspect of the present disclosure, the semiconductor devices illustrated in the assemblies of FIGS. 1-6 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, accelerator dies, etc.), or a mix of logic and memory dies (e.g., a memory controller die and a memory die controlled thereby).

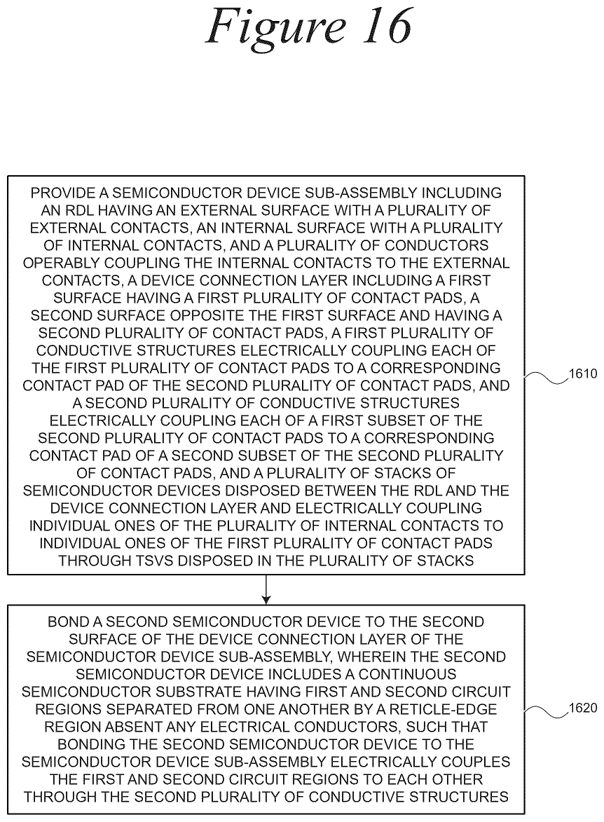

FIG. 16 is a flow chart illustrating a method of making a semiconductor device assembly. The method includes providing a semiconductor device sub-assembly including an RDL having an external surface with a plurality of external contacts, an internal surface with a plurality of internal contacts, and a plurality of conductors operably coupling the internal contacts to the external contacts, a device connection layer including a first surface having a first plurality of contact pads, a second surface opposite the first surface and having a second plurality of contact pads, a first plurality of conductive structures electrically coupling each of the first plurality of contact pads to a corresponding contact pad of the second plurality of contact pads, and a second plurality of conductive structures electrically coupling each of a first subset of the second plurality of contact pads to a corresponding contact pad of a second subset of the second plurality of contact pads, and a plurality of stacks of semiconductor devices disposed between the RDL and the device connection layer and electrically coupling individual ones of the plurality of internal contacts to individual ones of the first plurality of contact pads through TSVs disposed in the plurality of stacks (box 1610). The method further includes bonding a second semiconductor device to the second surface of the device connection layer of the semiconductor device sub-assembly, wherein the second semiconductor device includes a continuous semiconductor substrate having first and second circuit regions separated from one another by a reticle-edge region absent any electrical conductors, such that bonding the second semiconductor device to the semiconductor device sub-assembly electrically couples the first and second circuit regions to each other through the second plurality of conductive structures (box 1620).

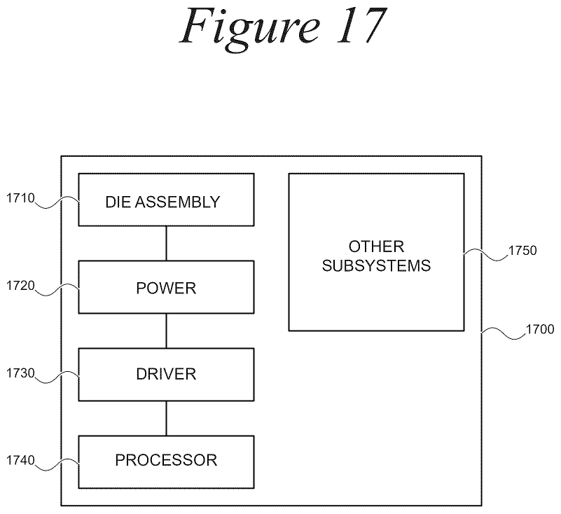

Any one of the semiconductor devices and semiconductor device assemblies described above with reference to FIGS. 1-15 can be incorporated into any of a myriad of larger and/or more complex systems, a representative example of which is system 1700 shown schematically in FIG. 17. The system 1700 can include a semiconductor device assembly (e.g., or a discrete semiconductor device) 1702, a power source 1704, a driver 1706, a processor 1708, and/or other subsystems or components 1710. The semiconductor device assembly 1702 can include features generally similar to those of the semiconductor devices described above with reference to FIGS. 1-15. The resulting system 1700 can perform any of a wide variety of functions, such as memory storage, data processing, and/or other suitable functions. Accordingly, representative systems 1700 can include, without limitation, hand-held devices (e.g., mobile phones, tablets, digital readers, and digital audio players), computers, vehicles, appliances and other products. Components of the system 1700 may be housed in a single unit or distributed over multiple, interconnected units (e.g., through a communications network). The components of the system 1700 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques. \

In other embodiments, the term “substrate” can refer to a package-level substrate upon which other semiconductor devices are carried, such as a printed circuit board (PCB), an interposer, or another semiconductor device.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a plurality of stacks of semiconductor devices, each stack of the plurality including multiple vertically-aligned semiconductor devices operably coupled by through-silicon vias (TSVs) to a plurality of external package contacts through a redistribution layer (RDL);
a device connection layer formed over the plurality of stacks of semiconductor devices and including a first plurality of contacts facing and coupled to the TSVs, a second plurality of contacts facing away from the TSVs, a first plurality of conductors operably coupling individual contacts of the first plurality to corresponding individual contacts of the second plurality, and a second plurality of conductors operably coupling individual contacts of the second plurality to other individual contacts of the second plurality; and
a multi-reticle semiconductor device disposed over the device connection layer, the multi-reticle semiconductor device including a continuous semiconductor substrate having a plurality of circuit regions separated from one another by a reticle-edge region absent any electrical conductors,
wherein the second plurality of conductors in the device connection layer operably interconnect the plurality of circuit regions.

2. The semiconductor device assembly of claim 1, wherein the RDL electrically couples the multi-reticle semiconductor device and the plurality of stacks of semiconductor devices to the plurality of external package contacts.

3. The semiconductor device assembly of claim 1, wherein the plurality of circuit regions of the multi-reticle semiconductor device is disposed in an active layer of the multi-reticle semiconductor device facing the device connection layer.

4. The semiconductor device assembly of claim 1, wherein the second plurality of conductors extends horizontally under the reticle-edge region of the multi-reticle semiconductor device.

5. The semiconductor device assembly of claim 1, wherein:
the multi-reticle semiconductor device includes a first bonding surface including a first planar dielectric surface and a third plurality of contacts, and
the device connection layer includes a second bonding surface including a second planar dielectric surface and the second plurality of contacts, and
the first bonding surface and the second bonding surface are hybrid-bonded to one another such that the first planar dielectric surface and the second planar dielectric surface are bonded by a dielectric-dielectric bond and such that each of the second plurality of contact pads is bonded to a corresponding one of the third plurality of contact pads by a metal-metal bond exclusive of any solder.

6. The semiconductor device assembly of claim 1, further comprising a plurality of through-stack vias extending from the device connection layer to the RDL, each of the through-stack vias comprising a continuously tapering body of conductive metal.

7. The semiconductor device assembly of claim 6, wherein each through-stack via of the plurality of through-stack vias electrically couples the multi-reticle semiconductor device to an external package contact of the plurality of external package contacts exclusive of connection to any circuitry of the plurality of stacks of semiconductor devices.

8. The semiconductor device assembly of claim 1, wherein at least one contact pad of the first plurality is not vertically aligned with any contact pad of the second plurality.

9. The semiconductor device assembly of claim 1, wherein every contact pad of the first plurality is vertically aligned with a corresponding contact pad of the second plurality.

10. A semiconductor device assembly, comprising:
a redistribution layer (RDL) including:
an external surface including a plurality of external contacts,
an internal surface including a plurality of internal contacts, and
a plurality of conductors operably coupling individual ones of the plurality of internal contacts to individual ones of the plurality of external contacts;
a device connection layer including:
a first surface having a first plurality of contact pads,
a second surface opposite the first surface and having a second plurality of contact pads,
a first plurality of conductive structures electrically coupling each of the first plurality of contact pads to a corresponding contact pad of the second plurality of contact pads, and
a second plurality of conductive structures electrically coupling each of a first subset of the second plurality of contact pads to a corresponding contact pad of a second subset of the second plurality of contact pads; and
a plurality of stacks of semiconductor devices disposed between the RDL and the device connection layer and electrically coupling individual ones of the plurality of internal contacts to individual ones of the first plurality of contact pads through TSVs disposed in the plurality of stacks.

11. The semiconductor device assembly of claim 10, wherein at least one contact pad of the first plurality of contact pads is not vertically aligned with any contact pad of the second plurality of contact pads.

12. The semiconductor device assembly of claim 10, wherein every contact pad of the first plurality of contact pads is vertically aligned with a corresponding contact pad of the second plurality of contact pads.

13. The semiconductor device assembly of claim 10, further comprising a plurality of through stack vias extending from the RDL to the device connection layer, each of the through-stack vias comprising a continuously tapering body of conductive metal.

14. A method of making a semiconductor device assembly, comprising:
providing a semiconductor device sub-assembly, the semiconductor device sub-assembly including:
a redistribution layer (RDL) including an external surface including a plurality of external contacts, an internal surface including a plurality of internal contacts, and a plurality of conductors operably coupling individual ones of the plurality of internal contacts to individual ones of the plurality of external contacts;
a device connection layer including a first surface having a first plurality of contact pads, a second surface opposite the first surface and having a second plurality of contact pads, a first plurality of conductive structures electrically coupling each of the first plurality of contact pads to a corresponding contact pad of the second plurality of contact pads, and a second plurality of conductive structures electrically coupling each of a first subset of the second plurality of contact pads to a corresponding contact pad of a second subset of the second plurality of contact pads; and
a plurality of stacks of semiconductor devices disposed between the RDL and the device connection layer and electrically coupling individual ones of the plurality of internal contacts to individual ones of the first plurality of contact pads through TSVs disposed in the plurality of stacks,
bonding a second semiconductor device to the second surface of the device connection layer of the semiconductor device sub-assembly, wherein the second semiconductor device includes a continuous semiconductor substrate having first and second circuit regions separated from one another by a reticle-edge region absent any electrical conductors, such that bonding the second semiconductor device to the semiconductor device sub-assembly electrically couples the first and second circuit regions to each other through the second plurality of conductive structures.

15. The method of claim 14, wherein bonding the second semiconductor device to the second surface of the device connection layer comprises forming a hybrid bond including dielectric-dielectric bonds and metal-metal bonds.

16. The method of claim 15, wherein the hybrid bond is exclusive of any solder material.

17. The method of claim 14, wherein providing the semiconductor device sub-assembly comprises hybrid bonding wafers including the plurality of stacks of semiconductor devices into a wafer stack.

18. The method of claim 14, wherein bonding the second semiconductor device to the semiconductor device sub-assembly comprises a wafer-level bonding operation.

19. The method of claim 14, further comprising forming, in the semiconductor device sub-assembly, through stack vias extending from the RDL to the device connection layer, each of the through-stack vias comprising a continuously tapering body of conductive metal.

20. The method of claim 14, further comprising forming, on the plurality of external contacts, a plurality of solder balls.
